(19) United States
(12) Patent Application Publication
(10) Pub. No.: US 2026/0209935 A1
(43) Pub. Date: Jul. 23, 2026

(54) SYSTEM AND METHODS FOR DIRECT LIQUID INJECTION OF VANADIUM PRECURSORS

(71) Applicant: ASM IP Holding B.V., Almere (NL)

(72) Inventors: Eric James Shero, Phoenix, AZ (US); Dieter Pierreux, Pepingen (BE); Bert Jongbloed, Oud-Heverlee (BE); Werner Knaepen, Leuven (BE); Charles Dezelah, Helsinki (FI); Qi Xie, Shanghai (CN); Petri Raisanen, Gilbert, AZ (US); Hannu Huotari, Espoo (FI); Paul Ma, Scottsdale, AZ (US); Vamsi Paruchuri, Mesa, AZ (US)

(21) Appl. No.: 19/569,486

(22) Filed: Mar. 17, 2026

Related U.S. Application Data
(62) Division of application No. 17/329,829, filed on May 25, 2021.
(60) Provisional application No. 63/030,184, filed on May 26, 2020.

(51) Int. Cl. C23C 16/455; C23C 16/34; C23C 16/448

(52) U.S. Cl. CPC C23C 16/455; C23C 16/34; C23C 16/4486

(57) ABSTRACT

Direct liquid injection systems and vapor deposition systems including direct liquid injection systems are disclosed. Exemplary direct liquid injection systems and related vapor deposition systems can be configured for forming vanadium containing layer on a substrate by cyclical deposition processes.

### CROSS-REFERENCE TO RELATED APPLICATIONS

This application is a divisional of U.S. application Ser. No. 17/329,829, entitled “SYSTEM AND METHODS FOR DIRECT LIQUID INJECTION OF VANADIUM PRECURSORS” and filed May 5, 2021, which claims priority to U.S. Provisional Ser. No. 63/030,184 , filed May 26, 2020, the contents of which are herein incorporated by this reference in their entirety.

### BACKGROUND OF THE DISCLOSURE

### Field of the Disclosure

The present disclosure relates generally to direct liquid injection of vanadium precursors.

### Description of the Related Art

Thin metal and metal compound layers can be formed on substrates and other structures through a cyclical deposition process, such as chemical vapor deposition or atomic layer deposition. Such layers are desirable, for example, in semiconductor processing for various purposes, such as for conductive diffusion barriers. Some metal precursors are difficult to provide with a high vapor flux and with low rates of decomposition. Accordingly, there is a need for a system and method that can provide metal precursors at a high vapor flux while avoiding the decomposition rates.

### SUMMARY

In one embodiment, a vapor deposition system is disclosed. The vapor deposition system can include a precursor source comprising a liquid vanadium precursor; a control valve in fluid communication with the precursor source, the control valve configured to control the liquid flow of the vanadium precursor from the precursor source; an injector in fluid communication with the control valve, the injector configured to vaporize the vanadium precursor; and a reaction chamber in fluid communication with the injector, the injector configured to deliver the vaporized vanadium precursor to the reaction chamber.

In some embodiments, the system includes the vanadium precursor comprises a vanadium halide. In some embodiments, the vanadium halide comprises vanadium tetrachloride. In some embodiments, the system includes a nitrogen precursor source in communication with the reaction chamber. In some embodiments, the vapor deposition system is configured to form a vanadium nitride layer on a substrate by contacting the substrate with the vanadium precursor from the injector and contacting the substrate with nitrogen from the nitrogen precursor source. In some embodiments, the injector comprises an atomizer positioned to spray atomized vanadium precursor on a hot plate. In some embodiments, the injector comprises an atomizer upstream of a heated conduit.

In another embodiment, a vapor deposition system includes a precursor source comprising a liquid vanadium halide precursor; an atomizer in fluid communication with the precursor source; a carrier gas in fluid communication with the atomizer; a heating element in fluid communication with the atomizer; and a reaction chamber in fluid communication with the heating element, the heating element configured to deliver vaporized precursor to the reaction chamber.

In some embodiments, the vanadium halide precursor comprises vanadium tetrachloride. In some embodiments, the system includes a nitrogen precursor source in communication with the reaction chamber. In some embodiments, the vapor deposition system is configured to form a vanadium nitride layer on a substrate by atomizing the liquid vanadium halide precursor with the carrier gas, vaporizing the atomized vanadium halide precursor and carrier gas, contacting the substrate with the vaporized vanadium halide precursor, and contacting the substrate with nitrogen from the nitrogen precursor source. In some embodiments, the heating element comprises a hot plate. In some embodiments, the heating element comprises a heated conduit. In some embodiments, the system includes a liquid flow meter configured to measure the flow of the liquid vanadium halide precursor from the precursor source to the atomizer.

In another embodiment, a method of forming a vanadium nitride layer on a substrate is disclosed. The method can include placing a substrate within a reaction chamber; metering a liquid vanadium halide precursor upstream of an injector; vaporizing the liquid vanadium halide precursor; and introducing the vaporized vanadium halide precursor into the reaction chamber to form a layer comprising vanadium on the substrate.

In some embodiments, vaporizing the liquid vanadium halide precursor comprises atomizing the liquid vanadium halide precursor with a carrier gas to form a spray and heating the spray to vaporize the vanadium halide precursor. In some embodiments, heating the spray comprises contacting the spray with a hot plate. In some embodiments, heating the spray comprises heating the spray within a heated conduit. In some embodiments, the vanadium halide precursor comprises vanadium tetrachloride. In some embodiments, the method includes introducing a nitrogen precursor into the reaction chamber to form a layer of vanadium nitride on the substrate.

In another embodiment, a direct liquid injection system includes a precursor source vessel comprising a liquid vanadium precursor; a liquid flow meter downstream of the precursor source vessel; and an injector downstream of the liquid flow meter.

In some embodiments, the injector comprises an atomizer and a heating element configured to vaporize atomized precursor received from the atomizer. In some embodiments, the heating element comprises a hot plate. In some embodiments, the heating element comprises a heated conduit. In some embodiments, the system includes a carrier gas source in fluid communication with the atomizer.

### RIEF DESCRIPTION OF THE DRAWINGS

FIG. 1A-B illustrate various systems for introducing a vanadium (V) precursor into a reaction chamber.

FIG. 2A-B illustrate a system for introducing a vanadium (V) precursor into a reaction chamber.

FIG. 3 illustrate a vapor deposition system for forming a vanadium containing layer on a substrate.

FIG. 4A-B illustrate exemplary processes for forming a vanadium nitride layer.

The drawings are provided to illustrate example embodiments described herein and are not intended to limit the scope of the disclosure.

### DETAILED DESCRIPTION

The present disclosure generally relates to methods and systems suitable for forming a layer on a surface of a substrate and to structures including the layer. More particularly, the disclosure relates to methods and systems for forming layers that include vanadium, such as vanadium nitride, using direct liquid injection (DLI) techniques.

Layers of vanadium nitride can be formed on substrates and other structures through a cyclical deposition process. The term “cyclic deposition process” or “cyclical deposition process” can refer to the sequential introduction of precursors (and/or reactants) into a reaction chamber to deposit a layer over a substrate or structure. Cyclical deposition processes can include processing techniques such as atomic layer deposition (ALD), cyclical chemical vapor deposition (cyclical CVD), hybrid cyclical deposition processes that include an ALD component and a cyclical CVD component, variations of ALD (e.g. plasma enhanced atomic layer deposition), variations of CVD (e.g. plasma enhanced chemical vapor deposition), etc.

The term “atomic layer deposition” can refer to a vapor deposition process m which deposition cycles, typically a plurality of consecutive deposition cycles, are conducted in a reaction chamber. The term atomic layer deposition, as used herein, is also meant to include processes designated by related terms, such as chemical vapor atomic layer deposition, when performed with alternating pulses of precursor(s)/reactive gas(es), and purge (e.g., inert carrier) gas(es)., such as by purging or pumping down the reaction chamber between provision of precursors or moving the substrate between zones

Generally, for ALD processes, mechanisms are provided to separate mutually reactive precursors in the vapor phase so that reactions are predominantly or exclusively surface reactions. In space divided ALD, the substrate can be moved to cycle through different zones that are provided with different reactants. In time divided ALD, during each cycle, in one phase a reactant (a precursor) is introduced to a reaction chamber and is chemisorbed on a deposition surface (e.g., a substrate surface that can include a previously deposited material from a previous ALD cycle or other material), forming about a monolayer or sub-monolayer of material. The precursor and conditions can be selected such that the adsorbed layer tends not continue to react with the precursor in the chamber and the adsorption is self-limiting. For example, the chemisorbed species can represent the precursor or a fragment thereof, including ligands that prevent further reaction after the chemisorbed species covers the substrate surface. Thereafter, in some cases, another reactant (e.g., another precursor or other reactant such as a reducing agent to strip ligands) may subsequently be introduced into the reaction chamber for use in converting the chemisorbed species to the desired material on the deposition surface (e.g., by stripping or replacing ligands from the chemisorbed species). A cycle can include 2, 3, 4 or any number of different reactants in selected sequences, any the cycles need not be identical. For example, one reactant can supply a particular element to the growing film every X cycles, where X is selected to supply a certain atomic proportion of the element to the growing film. Between different reactants the chamber is evacuated of the prior reactant, such as by pumping down the chamber for a period of time or purging with inert gas (typically nitrogen or a noble gas), to remove any excess precursor from the reaction chamber and/or remove any excess reactant and/or reaction byproducts from the reaction chamber. Separating the reactants in this way minimizes or avoids gas phase or CVD-like reactions and limits the reactions to surface reactions at the substrate for greater control and excellent step coverage of the growing film, although some limited residual gases from prior reactant pulses typically remain in realistic processes.

In CVD, multiple reactants are typically simultaneously provided to a reaction chamber, where the substrate is kept hot enough for the reactants to react and deposit a desired material.

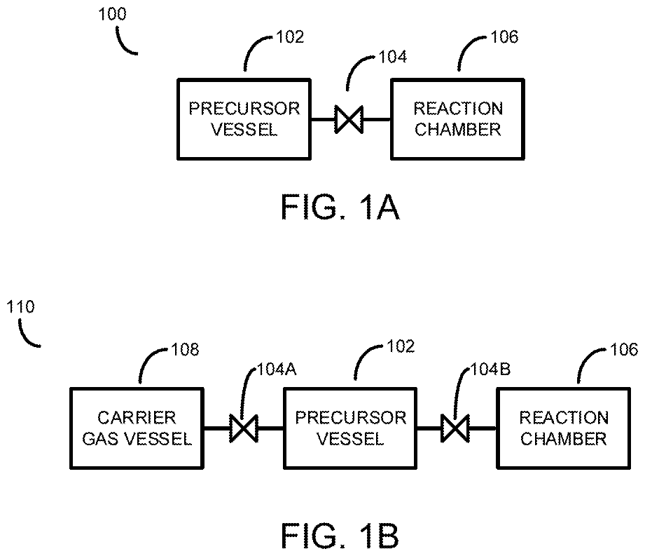

Many metal vapor precursors are naturally liquid under standard conditions. Various types of reactant vapor sources can be used to provide reactant vapor for these deposition processes, such as the exemplary systems shown in FIG. 1A and FIG. 1B. For example, liquid reactant sources of the precursor can supply liquid reactant which can be vaporized, and the resultant vapor can be delivered to the reactor. One example of a liquid reactant supply system can be a vapor drawn system, as illustrated by exemplary system 100 of FIG. 1A. In vapor drawn systems, a precursor can be heated in a precursor vessel 102 to increase vapor pressure of the precursor above the liquid. The vapor can then be periodically drawn from the precursor vessel 102 and introduced into the reaction chamber 106 (via a flow controller 104) for use in a vapor deposition process on a substrate surface.

Another liquid reactant supply system can include a bubbler system for vaporizing liquid reactant. In bubbler systems, as illustrates by exemplary system 110 of FIG. 1B. For example, a carrier gas vessel 108 can provide a carrier gas to a precursor vessel 102 containing a liquid precursor (via a flow controller 104A). The carrier gas from carrier gas vessel 108 creates bubbles within the liquid precursor, which forms a vapor. The vapor can be introduced into the reaction chamber 106 (via flow controller 104B) for use in the vapor deposition process. The precursor vessel 102 is typically constantly heated in order to increase vapor pressure so that useful concentrations of the precursor are available for the vapor deposition process.

Vapor drawn and bubbler systems can be used for ALD. When vapor drawn and bubbler systems are used to supply vapor for ALD processes, the precursors vessels can be heated constantly. With constant heating, there is more time to efficiently produce sufficient vapor for an ALD pulse and to more reliably saturate the substrate surface with the precursor. Other systems, such as a direct liquid injection system, are typically not used for ALD. In a direct liquid injection system, the system has little time for vaporizing the atomized flow, and therefore is less consistent in delivering fully vaporized reactant to the reaction chamber. Furthermore, in direct liquid injection systems, delivery of liquid downstream of its injector may lead to clogging and contamination for some ALD processes. Additionally, a direct liquid injection system can meter the flow of a liquid precursor and, due to that metering, the system can closely control the dosage of a precursor. In some ALD processes, however, obtaining a precise dosage may be less important than providing a sufficient dosage that will lead to saturation. Thus, conventional ALD systems often do not utilize direct liquid injection systems.

Vapor drawn and bubbler systems can be viable for a variety of precursors, including halide precursors, metal-organic precursors, etc. For example, vapor drawn and bubbler systems can work well in forming reactant vapors for halides such as titanium chloride (TiCl4), which is used in many process recipes in the semiconductor industry, particularly for forming titanium nitride as a popular conductive diffusion barrier. However, the inventors have found that vanadium precursors, particularly vanadium halides like vanadium tetrachloride, are more susceptible to decomposition, particularly when heated over time. This can cause several process stability issues for vapor drawn and/or bubbler systems. For example, liquid vanadium tetrachloride can decompose and release chlorine when heated over in vapor drawn and/or bubbler systems, which allows for chlorine gas to flow into the reaction chamber and interfere with the deposition and etch the deposited film or other exposed structures on the substrate. Additionally, the introduction of the carrier gas in bubbler systems can also cause the vanadium precursor to decompose over time. In order to avoid stability issues for liquid vanadium precursors, there is a need for a system that provides high precursor vapor flux to the reaction chamber while avoiding thermal composition.

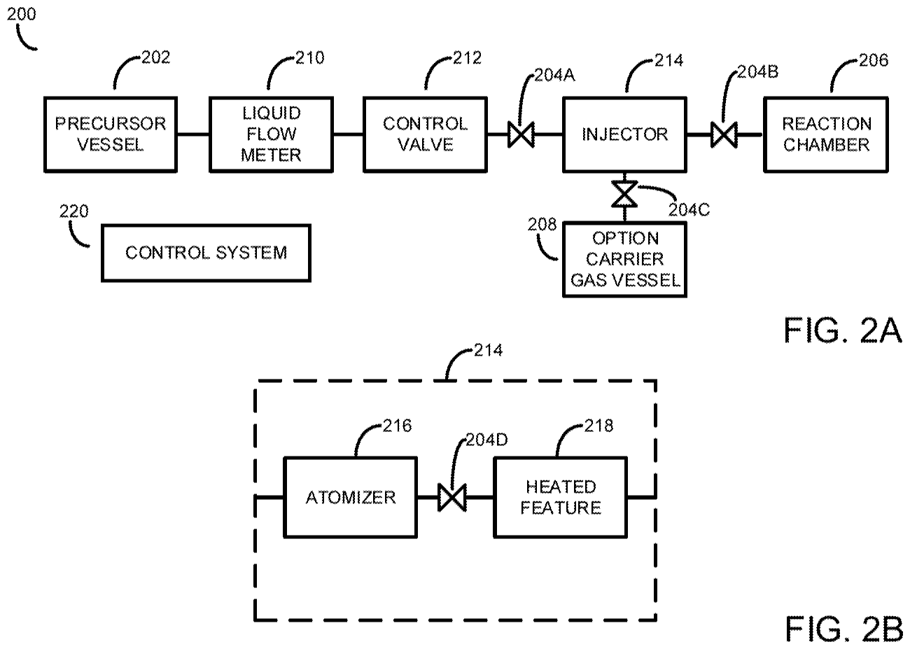

A direct liquid injection system can be used to avoid these process stability issues for vanadium precursors. As shown in FIG. 2, an exemplary direct liquid injection system 200 which can include a precursor vessel 202, a liquid flow meter 210, a control valve 212, a injector 214, and a reaction chamber 206. The precursor vessel 202 can be connected to the liquid flow meter 210. The liquid flow meter 210 can be connected to the control valve 212. The control valve 212 can be connected to the injector 214. The injector 214 can be connected to the reaction chamber 206. As shown in FIG. 2, the precursor vessel 202 can hold the vanadium precursor at room temperature and in liquid form. In other embodiments, the precursor vessel may be subject to a low amount of heating such that the precursor remains in liquid form. For example, the embodiments disclosed herein can maintain the liquid vanadium precursor at a temperature in a range of 15 degrees Celsius to 120 degrees Celsius. In some embodiments, the liquid vanadium precursor is maintained at a temperature in a range of 18 degrees Celsius to 27 degrees Celsius. In some embodiments, the liquid vanadium precursor in precursor vessel 202 is maintained at a temperature in a range of 20 degrees Celsius to 25 degrees Celsius. The liquid flow meter 210 can measure the amount of liquid precursor that flows out of the precursor vessel 202 and to the control valve 212. The control valve 212 can control the amount of the liquid precursor that flows from the precursor vessel 202 and into the injector 214. The injector 214 converts the liquid precursor to vapor for delivering the precursor into the reaction chamber 206.

The direct liquid injection system 200 can deliver a vaporized vanadium precursor to a reaction chamber in the following manner. A vanadium precursor can be stored as a liquid at room temperature (or at a temperature sufficient to maintain the precursor in liquid form) within a precursor vessel. The precursor vessel can be connected to a liquid flow meter and control valve. The liquid flow meter and control valve can control a precise amount of the liquid vanadium precursor that is delivered to the injector. Once delivered to the injector, the liquid vanadium precursor can be converted from liquid to vapor form, hence it can be introduced into the reaction chamber. Converting from liquid to vapor form, or vaporizing, a precise amount liquid vanadium precursor only as needed, immediately before delivering it to the reaction chamber can beneficially reduce the risk of precursor decomposition while providing high vapor flow rates to the reaction chamber. Accordingly, direct liquid injection systems for vanadium precursors can improve the process stability.

FIG. 2B illustrates an expanded view of the injector 214 employed in the direct liquid injection system 200. For example, the injector 214 can include an atomizer 216. The atomizer 216 can be connected to the control valve 212 and can be used to atomize the vanadium precursor with an optional carrier gas from an optional carrier gas vessel 208. Atomizing the vanadium precursor transforms the liquid precursor into a spray with very fine droplets. Carrier gas may also be supplied to aid the atomization process. The spray can be delivered to a heated feature 218, such as heating element, for example, where the fine droplets of precursor can be readily transformed into a true vapor.

In various embodiments, the direct liquid injection system can include a hot plate as the heating element or heated feature 218 of the injector 214. The hot plate can be raised to a temperature that can instantly vaporize the vanadium precursor when the atomized precursor contacts the hot plate.

In various embodiments, the direct liquid injection system can include a heated conduit, or tube as the heated feature 218 of the injector. The heated tube can have a tube-like shape of a specified length and with a hollowed center. A heater can be connected to the outer surface of the tube, which can be used to apply heat through the tube. The heated tube can be used in combination with an atomizer 216. The atomizer 216 can send the atomized vanadium precursor through the length of tube. The spray can be vaporized as it travels through the heated feature 218, e.g., heated tube. The heated tube can vaporize the vanadium precursor in a gentler manner as compared to other injectors, such as the hot plate. The gentle heating can be beneficial for further reducing risk of thermal decomposition prior to delivery to the substrate.

In various embodiments, a control system 220 can be implemented with the direct liquid injection system. The control system 220 can provide electronic circuitry and mechanical components to selectively control the operation of valves, manifolds, pumps and other equipment included in the direct liquid injection system and the reaction chamber. The control system 220 can also control timing of the system sequences, temperature of the substrate and reaction chamber, and pressure of the reaction chamber and various other operations necessary to provide proper operation of the direct liquid injection system. The control system 220 can include software and electrically or pneumatically controlled valves to control flow of precursors, reactants, purge gasses, wafers, and other materials into and out of the reaction chamber. The control system 220 can include modules such as a software or hardware component, e.g., a FPGA or ASIC, which performs certain tasks. A module can advantageously be configured to reside on the addressable storage medium of the control system and be configured to execute one or more processes.

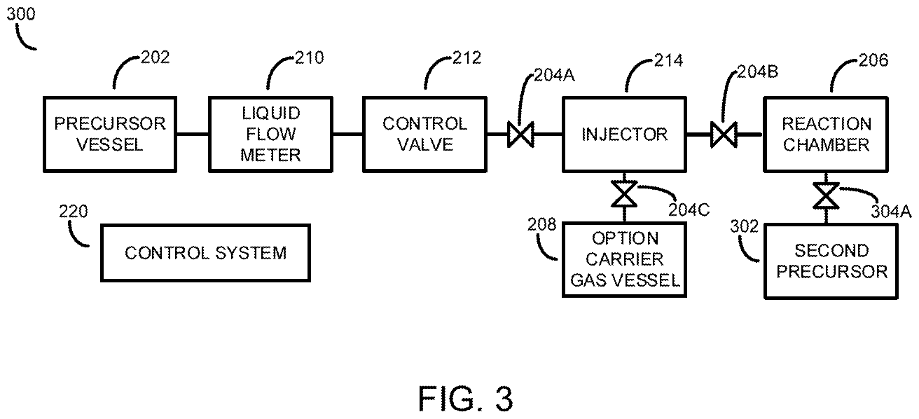

FIG. 3 illustrates an exemplary vapor deposition system 300 including the direct liquid injection systems of the current disclosure. Components, assemblies, and features previously described in relation to direct liquid injection system 200 are not repeated herein in the interest of brevity. In more detail, the vapor deposition system 300 includes, a precursor source (i.e., precursor vessel 202) comprising a liquid vanadium precursor, a control valve 212 in fluid communication with the precursor source 202. For example, the control valve 212 can be configured to control the liquid flow of the vanadium precursor from the precursor source, i.e., precursor vessel 2020. The vapor deposition system can further include, an injector 214 in fluid communication with the control valve 212, the injector 214 being configured to vaporize the vanadium precursor. The vapor deposition system 300 further comprises a reaction chamber 206 in fluid communication with the injector 214, the injector 214 being configured to deliver the vaporized vanadium to the reaction chamber 206.

The exemplary vapor deposition system 300 can include a precursor source 202 (or precursor vessel) containing a vanadium precursor, such as, a vanadium halide, for example. For example, the vanadium halide may comprise vanadium tetrachloride (VCl4).

The exemplary vapor deposition system 300 can further include a second precursor source 302, such as, a nitrogen precursor source, for example. The nitrogen precursor source 302 can be in communication with the reaction chamber.

In some embodiments of the disclosure, the exemplary vapor deposition system 300 can be configured to form a vanadium nitride layer on a substrate by contacting the substrate with a vanadium precursor from the injector 214 and contacting the substrate with nitrogen from the second precursor source 302, such as, a nitrogen precursor source, for example.

The exemplary vapor deposition system 300 (FIG. 3) may further comprise an injector including an atomizer 216 positioned to spray atomized vanadium precursor on a hot plate. In some embodiments, the injector comprises an atomizer that can be positioned to spray atomized vanadium precursor on a hot plate.

Vapor deposition system 300 may further comprise, a precursor source (i.e., vessel 202) comprising a liquid vanadium halide precursor; an atomizer in fluid communication with the precursor source (see expanded view of injector in FIG. 2B); a carrier gas in fluid communication with the atomizer; a heating element in fluid communication with the atomizer; and a reaction chamber in fluid communication with the heating element, the heating element configured to deliver vaporized precursor to the reaction chamber 206.

The vapor deposition system 300 may further comprise a nitrogen precursor source 302 in communication with the reaction chamber 206. For example, the vapor deposition system 300 can be configured to form a vanadium nitride layer on a substrate by atomizing a liquid vanadium halide precursor with a carrier gas, vaporizing the atomized vanadium halide precursor and carrier gas, contacting the substrate with the vaporized vanadium halide precursor, and contacting the substrate with nitrogen from the nitrogen precursor source. For example, the heating element configured to deliver vaporized precursor to the reaction chamber can comprise a hot plate or a heated conduit. The vapor deposition 300 may also include a liquid flow meter 210 configured to measure the flow of the liquid vanadium halide precursor from the precursor source (i.e., precursor vessel 202) to the atomizer 216.

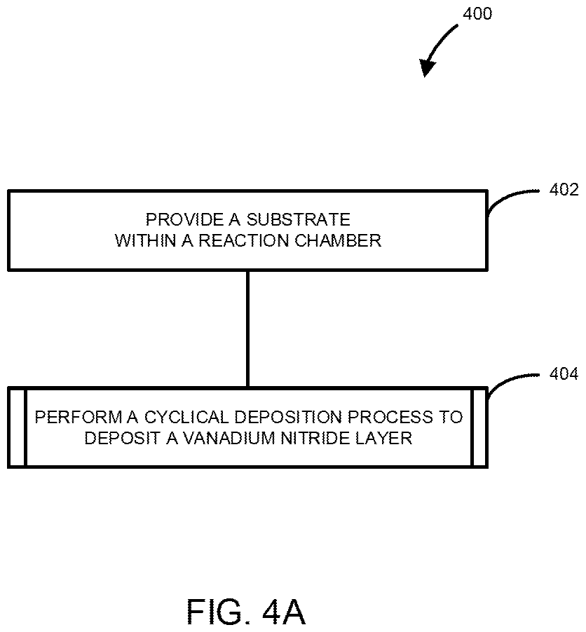

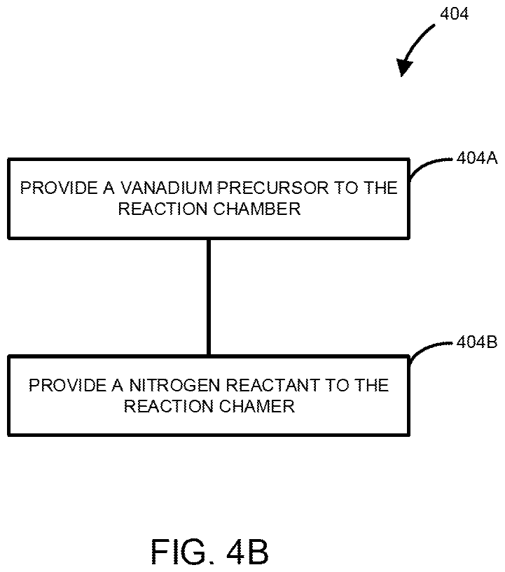

An example method of forming a vanadium compound layer, and particularly a vanadium nitride (VN) layer on substrate will now be described. The vanadium nitride layer can include various ratios of vanadium to nitrogen. A vanadium nitride layer can include additional elements, such as oxygen (e.g., a vanadium oxynitride layer) and the like. An exemplary method for forming a vanadium compound layer is illustrated with reference to process 400 of FIG. 4A. In more detail, a substrate is provided within a reaction chamber (process 402). The substrate can be heated to a temperature between approximately 20° C. and approximately 800° C. The pressure within the reaction chamber can also be regulated. For example, in some embodiments of the disclosure, the pressure within the reaction chamber may be less than 760 Torr or between 10 Torr and 760 Torr. Once the appropriate temperature and pressure conditions are met, a vanadium nitride layer can be deposited onto the surface of the substrate using a cyclical deposition process and a direct liquid injection system (cyclical deposition process 404) .

The direct liquid injection system, such as those systems described herein, can vaporize a vanadium halide precursor (such as vanadium tetrachloride, VCl4), which can then be delivered to the reaction chamber for adhering the precursor onto the substrate. For example, FIG. 4B illustrates in more detail the cyclical deposition process 404, in which a vanadium precursor is provided to the reaction chamber (step 404A).

After the vanadium halide precursor is introduced into the reaction chamber, excess reactant and any byproduct can be removed, such as in a purge step.

Subsequently, a nitrogen reactant (such as ammonia, NH3, or hydrazine, N2H4) is introduced into the reaction chamber and reacts with the adsorbed species of the vanadium precursor, to form a vanadium nitride layer on the substrate, as illustrated in exemplary cyclical deposition process 404 FIG. 4B, in which a nitrogen reactant is provided to the reaction chamber (step 404B). Additional nitrogen reactants may include, a substituted hydrazine compound such as an alkyl-hydrazine selected from the group consisting of: tertbutylhydrazine (C4H9N2H3), methylhydrazine (CH3NHNH2), dimethylhydrazine (C2H8N2), and diethylhydrazine (C4H12N2). Additionally, the use of a plasma to a generate a nitrogen reactant may be employed, such as, for example, by the generation of a nitrogen based plasma from a nitrogen containing gas.

After the nitrogen reactant is introduced into the reaction chamber, an inert gas can be used to purge the chamber and remove any excess reactant and any reaction byproducts from the chamber. The deposition and purging steps can be alternately performed until the layer reaches the desired thickness.

The exemplar methods of the disclosure may further comprise forming a vanadium nitride layer on a substrate. For example, the methods can include, placing a substrate within a reaction chamber; metering a liquid vanadium halide precursor upstream of an injector; vaporizing the liquid vanadium halide precursor; and introducing the vaporized vanadium halide precursor into the reaction chamber to form a layer comprising vanadium on the substrate. The methods can also comprise, atomizing the liquid vanadium halide precursor with a carrier gas to form a spray and heating the spray to vaporize the vanadium halide precursor. For example, heating the spray can comprise contacting the spray with a hot plate or within a heated conduit.

Additional methods for forming a vanadium nitride layer on a substrate or surface are described in U.S. Provisional Application No. 62/949,307, which was filed on Dec. 17, 2019, and incorporated by reference herein.

In this disclosure, “gas” can include material that is a gas at normal temperature and pressure (NTP), a vaporized solid and/or a vaporized liquid, and can be constituted by a single gas or a mixture of gases, depending on the context. A gas other than the process gas, i.e., a gas introduced without passing through a gas distribution assembly, other gas distribution device, or the like, can be used for, e.g., sealing the reaction space, and can include a seal gas, such as an inert. In some cases, the term “precursor” can refer to a compound that contributes element(s) to the deposited film. The term “reactant” encompasses precursors but also encompasses reactants that do not contribute to the growing film, such as oxidizing, reducing or gettering agents that strip and volatilize ligands (and/or byproduct). The term “inert gas” can refer to a gas that does not take part in a chemical reaction and/or does not become a part of a film to an appreciable extent. Exemplary inert gases include noble gases such as He, Kr and Ar and any combination thereof. In some cases, nitrogen (N2), oxygen (O2) and hydrogen (H2) can be considered an inert gas if it does not react with the reactants of the process under the deposition conditions.

As used herein, the term “substrate” can refer to any underlying material or materials that can be used to form, or upon which, a device, a circuit, or a film can be formed. A substrate can include a bulk material, such as silicon (e.g., single-crystal silicon), other Group IV materials, such as germanium, or other semiconductor materials, such as a Group II-VI or Group III-V semiconductor materials, and can include one or more layers overlying or underlying the bulk material. Further, the substrate can include various features, such as recesses, protrusions, and the like formed within or on at least a portion of a layer of the substrate. By way of examples, a substrate can include bulk semiconductor material, such as a silicon wafer, and an insulating or dielectric material layer overlying at least a portion of the bulk semiconductor material.

As used herein, the term “film” and/or “layer” can refer to any continuous or non-continuous structure and material, such as material deposited by the methods disclosed herein. For example, film and/or layer can include two-dimensional materials, three-dimensional materials, nanoparticles or even partial or full molecular layers or partial or full atomic layers or clusters of atoms and/or molecules. A film or layer may comprise material or a layer with pinholes, which may be at least partially continuous.

While certain embodiments of the inventions have been described, these embodiments have been presented by way of example only, and are not intended to limit the scope of the disclosure. Indeed, the novel methods and systems described herein may be embodied in a variety of other forms. Furthermore, various omissions, substitutions and changes in the systems and methods described herein may be made without departing from the spirit of the disclosure. The accompanying claims and their equivalents are intended to cover such forms or modifications as would fall within the scope and spirit of the disclosure. Accordingly, the scope of the present inventions is defined only by reference to the appended claims.

Features, materials, characteristics, or groups described in conjunction with a particular aspect, embodiment, or example are to be understood to be applicable to any other aspect, embodiment or example described in this section or elsewhere in this specification unless incompatible therewith. All of the features disclosed in this specification (including any accompanying claims, abstract and drawings), and/or all of the steps of any method or process so disclosed, may be combined in any combination, except combinations where at least some of such features and/or steps are mutually exclusive. The protection is not restricted to the details of any foregoing embodiments. The protection extends to any novel one, or any novel combination, of the features disclosed in this specification (including any accompanying claims, abstract and drawings), or to any novel one, or any novel combination, of the steps of any method or process so disclosed.

Furthermore, certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a claimed combination can, in some cases, be excised from the combination, and the combination may be claimed as a subcombination or variation of a subcombination.

Moreover, while operations may be depicted in the drawings or described m the specification in a particular order, such operations need not be performed in the particular order shown or in sequential order, or that all operations be performed, to achieve desirable results. Other operations that are not depicted or described can be incorporated in the example methods and processes. For example, one or more additional operations can be performed before, after, simultaneously, or between any of the described operations. Further, the operations may be rearranged or reordered in other implementations. Those skilled in the art will appreciate that in some embodiments, the actual steps taken in the processes illustrated and/or disclosed may differ from those shown in the figures. Depending on the embodiment, certain of the steps described above may be removed, others may be added. Furthermore, the features and attributes of the specific embodiments disclosed above may be combined in different ways to form additional embodiments, all of which fall within the scope of the present disclosure. Also, the separation of various system components in the implementations described above should not be understood as requiring such separation in all implementations, and it should be understood that the described components and systems can generally be integrated together in a single product or packaged into multiple products.

For purposes of this disclosure, certain aspects, advantages, and novel features are described herein. Not necessarily all such advantages may be achieved in accordance with any particular embodiment. Thus, for example, those skilled in the art will recognize that the disclosure may be embodied or carried out in a manner that achieves one advantage or a group of advantages as taught herein without necessarily achieving other advantages as may be taught or suggested herein.

Conditional language, such as “can,” “could,” “might,” or “may,” unless specifically stated otherwise, or otherwise understood within the context as used, is generally intended to convey that certain embodiments include, while other embodiments do not include, certain features, elements, and/or steps. Thus, such conditional language is not generally intended to imply that features, elements, and/or steps are in any way required for one or more embodiments or that one or more embodiments necessarily include logic for deciding, with or without user input or prompting, whether these features, elements, and/or steps are included or are to be performed in any particular embodiment.

Conjunctive language such as the phrase “at least one of X, Y, and Z,” unless specifically stated otherwise, is otherwise understood with the context as used in general to convey that an item, term, etc. may be either X, Y, or Z. Thus, such conjunctive language is not generally intended to imply that certain embodiments require the presence of at least one of X, at least one of Y, and at least one of Z.

Language of degree used herein, such as the terms “approximately,” “about,” “generally,” and “substantially” as used herein represent a value, amount, or characteristic close to the stated value, amount, or characteristic that still performs a desired function or achieves a desired result. For example, the terms “approximately”, “about”, “generally,” and “substantially” may refer to an amount that is within less than 10% of, within less than 5 % of, within less than I% of, within less than 0.1 % of, and within less than 0.01 % of the stated amount. As another example, in certain embodiments, the terms “generally parallel” and “substantially parallel” refer to a value, amount, or characteristic that departs from exactly parallel by less than or equal to 15 degrees, 10 degrees, 5 degrees, 3 degrees, I degree, or 0.1 degree.

The scope of the present disclosure is not intended to be limited by the specific disclosures of preferred embodiments in this section or elsewhere in this specification, and may be defined by claims as presented in this section or elsewhere in this specification or as presented in the future. The language of the claims is to be interpreted broadly based on the language employed in the claims and not limited to the examples described in the present specification or during the prosecution of the application, which examples are to be construed as non-exclusive.

What is claimed is:

1. A method of forming a vanadium nitride layer on a substrate, comprising:
placing a substrate within a reaction chamber;
metering a liquid vanadium halide precursor upstream from an atomizer;
atomizing, through operation of the atomizer, the liquid vanadium halide precursor to form an atomized vanadium halide precursor;
vaporizing the atomized vanadium halide precursor to form a vaporized vanadium halide precursor;
introducing the vaporized vanadium halide precursor into the reaction chamber; and
alternating introducing the vaporized vanadium halide precursor into the reaction chamber with a pulse of an inert purge gas into the reaction chamber.

2. The method of claim 1, wherein the introducing the vaporized vanadium halide precursor into the reaction chamber forms a layer comprising vanadium on the substrate.

3. The method of claim 2, further comprising introducing a nitrogen precursor into the reaction chamber to form a layer of vanadium nitride on the substrate.

4. The method of claim 3, wherein the nitrogen precursor comprises one or more of ammonia and hydrazine.

5. The method of claim 4, further comprising generating a nitrogen-based plasma from the nitrogen precursor.

6. The method of claim 4, further comprising providing a second pulse of the inert purge gas to the reaction chamber after introducing the nitrogen precursor into the reaction chamber.

7. The method of claim 6, further comprising repeating the steps of introducing the vaporized vanadium halide precursor, alternating introducing the vaporized vanadium halide precursor into the reaction chamber with the pulse of the inert purge gas, introducing the nitrogen precursor into the reaction chamber, and providing the second pulse of the inert purge gas to the reaction chamber until a desired thickness of the vanadium nitride layer is formed on the substrate.

8. The method of claim 1, wherein atomizing the liquid vanadium halide precursor comprises atomizing the liquid vanadium halide precursor with a carrier gas to form a spray.

9. The method of claim 8, wherein vaporizing the liquid vanadium halide precursor comprises heating the spray.

10. The method of claim 9, wherein heating the spray comprises contacting the spray with a hot plate.

11. The method of claim 9, wherein heating the spray comprises heating the spray within a heated tube.

12. The method of claim 11, wherein the heated tube comprises a conduit and a heating element coupled to the conduit.

13. The method of claim 11, wherein the vaporized vanadium halide precursor is formed as the atomized vanadium halide precursor travels through the heated tube.

14. The method of claim 1, wherein the liquid vanadium halide precursor comprises vanadium tetrachloride.

15. The method of claim 1, wherein the vaporized vanadium halide precursor is introduced into the reaction chamber directly after vaporizing the liquid vanadium halide precursor.

16. The method of claim 1, wherein the introducing the vaporized vanadium halide precursor is by pulsing the vaporized vanadium halide precursor into the reaction chamber.

17. The method of claim 1, wherein a temperature of the liquid vanadium halide precursor is maintained in a precursor vessel at between 18 and 27 degrees Celsius.

18. The method of claim 1, wherein a pressure within the reaction chamber is between 10 Torr and 760 Torr.

19. The method of claim 1, wherein the vanadium nitride layer further comprises oxygen.

20. The method of claim 1, wherein the metering is through operation of a control valve and a liquid flow meter.
